(19) United States
(12) Patent Application Publication
(10) Pub. No.: US 2023/0072780 A1
(43) Pub. Date: Mar. 9, 2023

(54) DEVICE PROVIDING STABILIZATION IN THE CAPTURE OF IMAGES

(71) Applicant: TRIPLE WIN TECHNOLOGY(SHENZHEN) CO.LTD., Shenzhen (CN)

(72) Inventors: HSIANG-CHIEH YU, NewTaipei (TW); HO-KAI LIANG, New Taipei (TW); YE-QUANG CHEN, Tu-Cheng (TW)

(21) Appl. No.: 17/538,049

(22) Filed: Nov. 30, 2021

(30) Foreign Application Priority Data
Sep. 3, 2021 (CN) 202111034367.1

(51) Int. Cl. G02B 27/64; H04N 5/232; G01R 33/07

(52) U.S. Cl. CPC G02B 27/646; H04N 5/2328; G01R 33/072

(57) ABSTRACT

A device for stabilizing an image-capturing device against trembling and shaking includes a chip, an image sensor, a first connector, and a second connector. The image sensor collects light and converts same into an electrical signal. The first connector is used for receiving the electrical signal. The second connector is used for electrically coupling the first connector and the chip, wherein the second connector transmits the electrical signal to the chip. The stabilizing device is elastically suspended in place and tremors and shakes on the part of the stabilizing device are cancelled as they occur by reverse displacement based on magnetism and as controlled by Hall effect sensors. The chip can output control signal to the second connector, the second connector transmits the control signal to the first connector, the first connector transmits the control signal to the image sensor to control state of the image sensor.

### TECHNICAL FIELD

The present disclosure relates to imaging.

### BACKGROUND

With the development of optical image stabilization (OIS) technology, the optical image stabilization devices are widely used in electronic equipment such as cameras. The optical image stabilization device interacts with the system on chip (SOC) through the flexible printed circuit board (FPCB).

The length and large bending degree of the flexible printed circuit board may hinder rotation of the optical image stabilization device, rendering the optical image stabilization device ineffective, and reducing the reliability of data transmission between the system level chip and the optical image stabilization device.

Therefore, improvement is desired.

### BRIEF DESCRIPTION OF THE DRAWINGS

FIG. 1 is a schematic diagram of a stabilization device according to an embodiment of the present disclosure.

FIG. 2 is a schematic diagram of a connector of the device according to an embodiment of the present disclosure.

FIG. 3 is a schematic diagram of a stabilization device in another embodiment of the present disclosure.

FIG. 4 is a schematic diagram of a stabilization device in another embodiment of the present disclosure.

### DETAILED DESCRIPTION

The technical solutions in the embodiments of the present disclosure will be described in conjunction with the accompanying drawings in the embodiments of the present disclosure. Obviously, the described embodiments are some embodiments of the present disclosure, not all of them. Based on the embodiments of the present disclosure, all other embodiments obtained by those of ordinary skill in the art without creative work shall fall within the protection scope of the present disclosure.

The terms “first” and “second” are only used for descriptive purposes and cannot be understood as indicating or implying relative importance or implicitly indicating the number of indicated technical features. Thus, the features defining “first” and “second” may explicitly or implicitly include one or more of the features. In the description of the present disclosure, “multiple” means two or more, unless otherwise expressly and specifically defined.

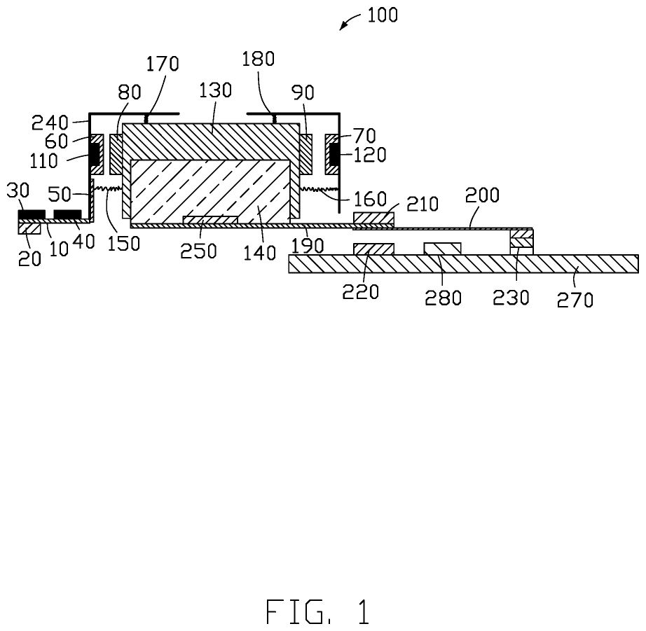

FIG. 1 illustrates an optical image stabilization device 100 in accordance with an embodiment of the present disclosure.

The optical image stabilization device 100 includes a circuit board 10, a connector 20, a drive chip 30, a gyroscope 40, a circuit board 50, a coil 60, a coil 70, a magnet 80, a magnet 90, a Hall sensor 110, a Hall sensor 120, a stabilization module 130, a camera module 140, an elastic element 150, an elastic element 160, an elastic element 170, an elastic element 180, a circuit board 190, a wireless connector 210, a connector 230, a wireless connector 220, a housing 240, an image sensor 250, a circuit board 270, and a system level chip 280.

The connector 20 is disposed on a first surface of the circuit board 10. In one embodiment, the connector 20 may be electrically connected to an external power supply (not shown) to supply power to the drive chip 30 and the gyroscope 40. The drive chip 30 and the gyroscope 40 are disposed on the second surface of the circuit board 10, and the drive chip 30 is electrically connected to the gyroscope 40 through the circuit board 10. The circuit board 10 is electrically connected to the circuit board 50, and the circuit board 50 is disposed on a first inner wall of the housing 240. The Hall sensor 110 is disposed on the first inner wall of the housing 240, an outside of the sensor 110 is surrounded by a coil 60, the sensor 120 is disposed on a second inner wall of the housing 240, the outside of the sensor 120 is surrounded by a coil 70, and the first inner wall of the housing 240 and the second inner wall of the housing 240 are disposed at intervals.

The stabilization module 130 is disposed on the circuit board 190 and accommodated in the housing 240, and the first inner wall of the housing 240 is connected to a first terminal of the elastic element 170. The second terminal of the elastic element 170 is connected to the first outer wall of the stabilization module 130, the second inner wall of the housing 240 is connected to a first terminal of the elastic element 180, and a second terminal of the elastic member elastic element 180 is connected to the first outer wall of the stabilization module 130.

The stabilization module 130 is suspended in the housing 240 by the elastic element 170 and the elastic element 180.

The magnet 80 is disposed on the second outer wall of the stabilization module 130, the magnet 90 is disposed on the third outer wall of the stabilization module 130, the second outer wall of the stabilization module 130 and the third outer wall of the stabilization module 130 are disposed adjacent to the first outer wall of the stabilization module 130, and the second outer wall of the stabilization module 130 is disposed opposite to the third outer wall of the stabilization module 130. The stabilization module 130 is surrounded and disposed outside the camera module 140, the image sensor 250 is disposed on the bottom surface of the camera module 140, and the image sensor 250 is disposed on the circuit board 190.

The camera module 140 includes a lens, which can receive light for imaging on the image sensor 250. The image sensor 250 can convert the optical signal of the external image into an electrical signal, which can represent the image information of the external image.

The gyroscope 40 can detect trembling and shaking of the optical image stabilization device 100. If the gyroscope 40 detects the shake of the optical image stabilization device 100, the gyroscope 40 transmits the shake information of the optical image stabilization device 100 to the drive chip 30, and the shake information represents the shake displacement of the optical image stabilization device 100. When the drive chip 30 receives the shake information, the drive chip 30 generates a current, which flows through the coil 60 through the circuit board 10 and the circuit board 50. The coil 60 can generate a first magnetic field. The stabilization module 130 is located in the first magnetic field and is displaced due to Lorentz force. The camera module 140 and the image sensor are also displaced with the stabilization module 130. The displacement direction is opposite to the direction of shake at an instant of time, this is called reverse displacement and eliminates the influence of the trembling or shaking on the image sensor 250. Similarly, the coil 70 may generate a second magnetic field to displace the stabilization module 130.

The first terminal of the elastic element 150 is connected to the second outer wall of the stabilization module 130, the second terminal of the elastic element 150 is connected to the third inner wall of the housing 240, the first terminal of the elastic element 160 is connected to the third outer wall of the stabilization module 130, and the second terminal of the elastic element 160 is connected to the fourth inner wall of the housing 240. After the stabilization module 130 performs reverse displacement, the hall sensor 110 can detect its position relative to the magnet 80 and determine whether displacement of the stabilization module 130 is sufficient. If the displacement of the stabilization module 130 is not sufficient, the Hall sensor 110 transmits a signal to the drive chip 30 to control the stabilization module 130 to continue displacement. For example, if the stabilization module 130 is absolutely motionless, the distance between the hall sensor 110 and the magnet 80 is 0.2 mm, the shaking direction of the stabilization module 130 is the same as the direction of the magnet 80 close to the hall sensor 110, and the displacement is 0.1 mm. When the Hall sensor 110 detects the distance between the hall sensor 110 and the magnet 80 as being 0.2 mm, it is determined that the displacement of the stabilization module 130 is sufficient.

By reverse displacement of the stabilization module 130, the image captured by the image sensor 250 is not blurred or otherwise prejudiced. At this time, the elastic element 150 and the elastic element 160 restore the stabilization module 130 to original position through elastic deformation.

In one embodiment, during the elastic deformation of the elastic element 150 and the elastic element 160, an excessive or an insufficient elastic deformation may result in non-return of the stabilization module 130 to an original motionless position. The Hall sensor 110, detecting its relative position with the magnet 80, can effectively determine whether a post-displacement position of the stabilization module 130 is correct. If the stabilization module 130 does not return to an original position, a signal from the Hall sensor 110 can govern a signal to the drive chip 30, to control the stabilization module 130 to continue displacement.

It can be understood that the elastic element 150 and the elastic element 160 can cooperate with the Hall sensor 110 or the Hall sensor 120 to restore the stabilization module 130 to an original position without shaking.

The wireless connector 210 is disposed on the circuit board 190 and electrically connected to the image sensor 250, the wireless connector 220 is disposed at intervals from the wireless connector 210, the wireless connector 220 is disposed on the circuit board 270, and the circuit board 270 is disposed at intervals from the circuit board 190. The connector 230 is disposed on the first surface of the circuit board 200 and electrically connected to the first surface of the circuit board 270. It can be understood that the connector 230 can be electrically connected to an external power supply to supply power to the image sensor 250.

The wireless connector 220 is electrically connected to a system level chip 280, which is disposed on the first surface of the circuit board 270. The wireless connector 220 may include a general purpose input/output (GPIO) interface and an inter-integrated circuit (I2C) interface to interact with the system level chip 280 through a GPIO interface or an I2C interface, and the wireless connector 210 may also include a GPIO interface and an I2C interface, to interact with the image sensor 250 through a GPIO interface or an I2C interface.

For example, the system level chip 280 can generate a control signal and transmit it to the wireless connector 220 through the GPIO interface or I2C interface, and the wireless connector 220 can transmit the control signal to the wireless connector 210 wirelessly. The wireless connector 210 transmits the control signal to the image sensor 250 through the GPIO interface or I2C interface to control the image sensor 250 generally (for example, initializing the image sensor 250 and resetting the image sensor 250). The image sensor 250 can generate feedback and transmit it to the system level chip 280 through the wireless connector 210 and the wireless connector 220, for example, when an initialization of the image sensor 250 is completed and when a reset of the image sensor 250 fails.

In one embodiment, the wireless connector 210 may also include a CMOS sensor interface (CSI), and the wireless connector 220 may also include a CSI. When the image sensor 250 converts the optical signal of the external image into an electrical signal and transmits it to the wireless connector 210 through CSI, the wireless connector 210 wirelessly transmits the electrical signal to the wireless connector 220. The wireless connector 220 transmits the electrical signal to the system level chip 280 through CSI, and the system level chip 280 can process the electrical signal (for example, for filtering, noise reduction, high dynamic lighting rendering (HDR) correction) to obtain a processed image.

In one embodiment, the wireless mode can be wireless local area network (WLAN), BLUETOOTH, high-speed mm wave, ZIGBEE, IR, not being limited in the present disclosure.

In one embodiment, the system level chip 280 can also generate a control signal and transmit it to the wireless connector 220, which wirelessly transmits the control signal to the wireless connector 210, and the wireless connector 210 transmits the control signal to the image sensor 250 to control the image sensor 250 (for example, initializing the image sensor 250 and resetting the image sensor 250). The image sensor 250 can generate feedback and transmit it to the system level chip 280 through the wireless connector 210 and the wireless connector 220, for example, when an initialization of the image sensor 250 is completed, and when a reset of the image sensor 250 fails.

In the embodiment, the circuit board 200 is a flexible printed circuit board (FPCB). Compared with the prior art, the circuit board 200 in this embodiment is short in length and has low bending degree, not hindering the displacement of the stabilization module 130 and the rotation of the optical image stabilization device 100. The optical image stabilization device 100 transmits the electrical signal, control signal, and feedback signal representing the image information wirelessly through the wireless connector 210 and the wireless connector 220, shortens the length of the flexible printed circuit board, reduces bending of the flexible printed circuit board, and reduces the circuit layout complexity of the flexible printed circuit board. The stability of signal transmission is improved, which is conducive to the dynamic adjustment of the optical image stabilization device 100 in response to changes of the external environment.

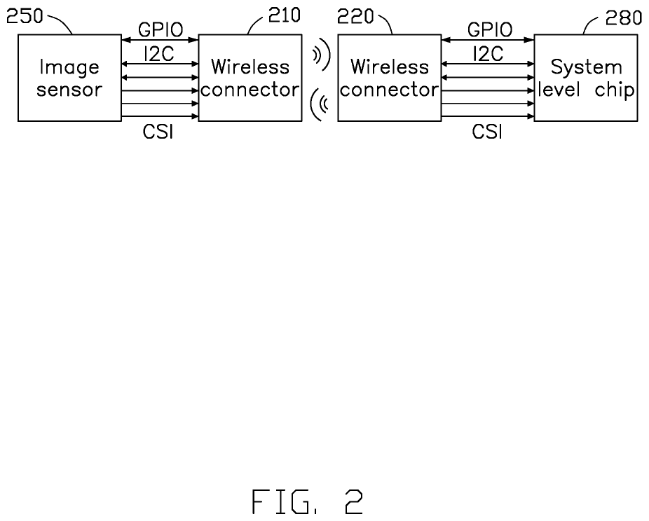

FIG. 2 shows a schematic diagram of the wireless connector 210 and the wireless connector 220 of the optical image stabilization device 100.

The wireless connector 210 is electrically connected to the image sensor 250 through the GPIO interface and the inter-integrated circuit (I2C) bus, the wireless connector 220 is electrically connected to the system level chip 280 through the GPIO interface and the I2C bus, and the signals between the wireless connector 210 and the wireless connector 220 can be transmitted to each other wirelessly.

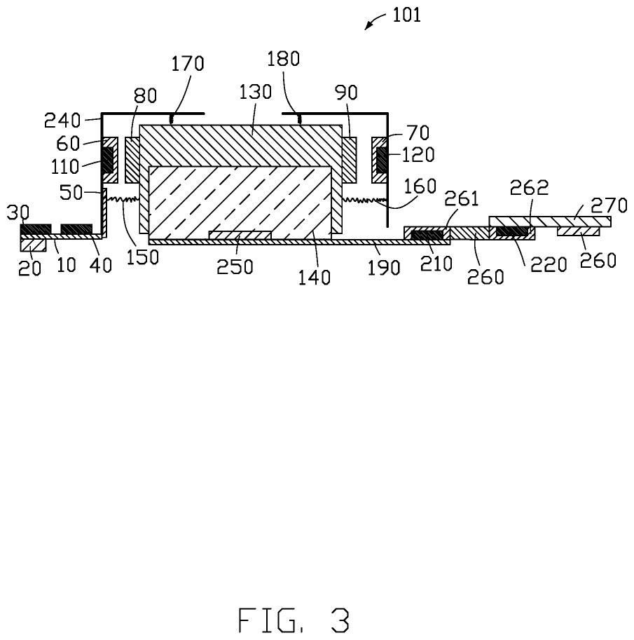

FIG. 3 illustrates an optical image stabilization device 101 in accordance with another embodiment of the present disclosure.

Compared with the optical image stabilization device 100, optical image stabilization device 101 provided by the present embodiment is provides a cover body 261 surrounding the outside of the wireless connector 210. The wireless connector 220 is also provided with a cover body 262 surrounding the outside, to reduce electromagnetic interference and prevent wireless signal overflow. The cover body 261 and the cover body 262 are connected through a waveguide 260 to reduce signal losses in wireless transmission and enhance the reliability of data transmissions.

In the embodiment, the material of the waveguide 260 is a material with low dielectric constant, for example, polyethylene (PE), polystyrene (PS), acrylonitrile butadiene styrene copolymer (ABS), polycarbonate (PC) engineering plastics. The air gap interval between the waveguide 260 and the wireless connector 210 or between the waveguide 260 and the wireless connector 220 is about 0.1-0.3 mm. It can be understood that the air gap interval can be appropriately adjusted according to the signal strength of the wireless signal transmitted between the wireless connector 210 and the wireless connector 220. The waveguide 260 is a soft waveguide and does not hinder rotation of the optical image stabilization device 101.

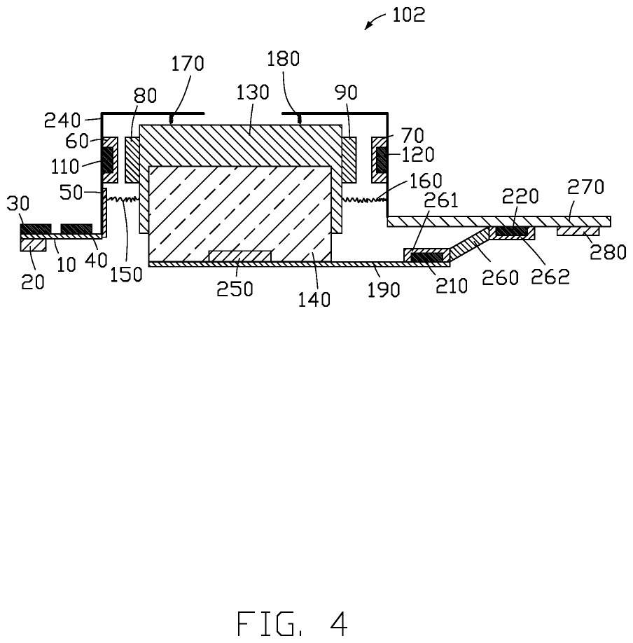

FIG. 4 illustrates an optical image stabilization device 102 in accordance with another embodiment of the present disclosure.

Compared with the optical image stabilization device 101, optical image stabilization device 102 provided by the present embodiment provides different faces to the wireless connector 210 and the wireless connector 220 for transmitting and receiving signals.

In the embodiment of FIG. 3, the wireless connector 210 and the wireless connector 220 use opposite sides for wireless signal transmission.

In the embodiment, the wireless connector 210 and the wireless connector 220 use faces for wireless transmission which are not set oppositely. The side of the wireless connector 210 and the bottom of the wireless connector 220 are embodiments of this disclosure, the transmission efficiencies of the side and bottom surfaces of the wireless connector 210 are different from those of the wireless signal. Therefore, different wireless signal transmission efficiencies can be achieved by relocating and reconfiguring the transmitting and receiving surfaces of the wireless connector 210 and the wireless connector 220.

Those of ordinary skill in the art should realize that the above embodiments are only used to illustrate the present disclosure, but not to limit the present disclosure. As long as they are within the essential spirit of the present disclosure, the above embodiments are appropriately made. Changes and changes fall within the scope of protection of the present disclosure.

What is claimed is:

1. An optical image stabilization device comprising:
a chip;
an image sensor sensing optical signal of an external image and converting the optical signal of the external image into an electrical signal;
a first connector receiving the electrical signal; and
a second connector electrically coupling the first connector and the chip; wherein the second connector transmits the electrical signal to the chip;
wherein the chip outputs control signal to the second connector, the second connector transmits the control signal to the first connector, the first connector transmits the control signal to the image sensor to control state of the image sensor.

2. The optical image stabilization device of claim 1, wherein:
the first connector is disposed on the first circuit board, the second connector is disposed on the second circuit board, and the first circuit board and the second circuit board are disposed at intervals.

3. The optical image stabilization device of claim 2, wherein:
the first connector comprises a first cover body, the first cover body surrounds an exterior of the first connector, the second connector comprises a second cover body, the second cover body surrounds an exterior of the second connector.

4. The optical image stabilization device of claim 1, wherein:
the first cover body is connected to the second cover body through a waveguide.

5. The optical image stabilization device of claim 3, wherein:
the optical image stabilization device further comprises a housing, a stabilization module, a first elastic element, a second elastic element, the stabilization module is received in the housing, a first outer wall of the stabilization module is connected to a first terminal of the first elastic element, a second terminal of the first elastic element is connected to a first inner wall of the housing, the first outer wall of the stabilization module is connected to a first terminal of the second elastic element, a second terminal of the second elastic element is connected to an second inner wall of the housing, the first elastic element and the second elastic element suspend the stabilization module in the housing, and the first inner wall of the housing is arranged opposite to the second inner wall of the housing.

6. The optical image stabilization device of claim 5, wherein:
the optical image stabilization device further comprises a first coil, a second coil, a first hall element, a second hall element, a first magnet, and a second magnet, the first hall element is disposed on the first inner wall of the housing, the second hall element is disposed on the second inner wall of the housing, the first coil is surrounded and disposed outside the first hall element, the second coil is surrounded and disposed outside the second hall element, the first magnet is disposed on the first outer wall of the stabilization module, and the second magnet is disposed on the second outer wall of the stabilization module.

7. The optical image stabilization device of claim 6, wherein:
the optical image stabilization device further comprises a gyroscope and a drive chip, the gyroscope is disposed on the third circuit board, the gyroscope detects whether the optical image stabilization device shakes; the drive chip is electrically coupled to the gyroscope; when the gyroscope detects the shake of the optical image stabilization device, the drive chip controls reverse displacement of the stabilization module to eliminate the shake.

8. The optical image stabilization device of claim 7, wherein:
when the stabilization module is reversely displaced, the first hall element detects the relative position between the stabilization module and the first magnet, and determines whether displacement of the stabilization module is completed; if the displacement of the stabilization module is not completed, the first hall element transmits a signal to the drive chip to control the stabilization module to continue reverse displacement.

9. The optical image stabilization device of claim 8, wherein:
the optical image stabilization device further comprises a third elastic element and a fourth elastic element, a first terminal of the third elastic element is connected to the second outer wall of the stabilization module, a second terminal of the third elastic element is connected to a third inner wall of the housing, a first terminal of the fourth elastic element is connected to a third outer wall of the stabilization module, a second terminal of the fourth elastic element is connected to a fourth inner wall of the housing; the second outer wall of the stabilization module and the third outer wall of the stabilization module are disposed adjacent to the first outer wall of the stabilization module, the second outer wall of the stabilization module is disposed opposite to the third outer wall of the stabilization module, and the third inner wall of the housing is disposed opposite to the fourth inner wall of the housing.

10. The optical image stabilization device of claim 9, wherein:
after the drive chip controls the reverse displacement of the stabilization module, the third elastic element and the fourth elastic element restore the stabilization module to a position without shaking through elastic deformation.

11. An optical image stabilization device comprising:
a chip;
an image sensor sensing optical signal of an external image and converting the optical signal of the external image into an electrical signal;
a first connector receiving the electrical signal;
a second connector electrically coupling the first connector and the chip; wherein the second connector transmits the electrical signal to the chip; and
wherein the chip outputs control signal to the second connector, the second connector transmits the control signal to the first connector, the first connector transmits the control signal to the image sensor to control state of the image sensor.
wherein the first connector is disposed on the first circuit board, the second connector is disposed on the second circuit board, and the first circuit board and the second circuit board are disposed at intervals; the first connector comprises a first cover body, the first cover body surrounds an exterior of the first connector, the second connector comprises a second cover body, the second cover body surrounds an exterior of the second connector; the first cover body is connected to the second cover body through a waveguide.

12. The optical image stabilization device of claim 11, wherein:
the optical image stabilization device further comprises a housing, a stabilization module, a first elastic element, a second elastic element, the stabilization module is received in the housing, a first outer wall of the stabilization module is connected to a first terminal of the first elastic element, a second terminal of the first elastic element is connected to a first inner wall of the housing, the first outer wall of the stabilization module is connected to a first terminal of the second elastic element, a second terminal of the second elastic element is connected to an second inner wall of the housing, the first elastic element and the second elastic element suspend the stabilization module in the housing, and the first inner wall of the housing is arranged opposite to the second inner wall of the housing.

13. The optical image stabilization device of claim 12, wherein:
the optical image stabilization device further comprises a first coil, a second coil, a first hall element, a second hall element, a first magnet, and a second magnet, the first hall element is disposed on the first inner wall of the housing, the second hall element is disposed on the second inner wall of the housing, the first coil surrounds an exterior of the first hall element, the second coil surrounds an exterior of the second hall element, the first magnet is disposed on the first outer wall of the stabilization module, and the second magnet is disposed on the second outer wall of the stabilization module.

14. The optical image stabilization device of claim 13, wherein:
the optical image stabilization device further comprises a gyroscope and a drive chip, the gyroscope is disposed on the third circuit board, the gyroscope detects whether the optical image stabilization device shakes; the drive chip is electrically coupled to the gyroscope; when the gyroscope detects the shake of the optical image stabilization device, the drive chip controls reverse displacement of the stabilization module to eliminate the shake.

15. The optical image stabilization device of claim 14, wherein:
when the stabilization module is reversely displaced, the first hall element detects the relative position between the stabilization module and the first magnet, and determines whether displacement of the stabilization module is completed; if the displacement of the stabilization module is not completed, the first hall element transmits a signal to the drive chip to control the stabilization module to continue reverse displacement.

16. The optical image stabilization device of claim 15, wherein:
the optical image stabilization device further comprises a third elastic element and a fourth elastic element, a first terminal of the third elastic element is connected to the second outer wall of the stabilization module, a second terminal of the third elastic element is connected to a third inner wall of the housing, a first terminal of the fourth elastic element is connected to a third outer wall of the stabilization module, a second terminal of the fourth elastic element is connected to a fourth inner wall of the housing; the second outer wall of the stabilization module and the third outer wall of the stabilization module are disposed adjacent to the first outer wall of the stabilization module, the second outer wall of the stabilization module is disposed opposite to the third outer wall of the stabilization module, and the third inner wall of the housing is disposed opposite to the fourth inner wall of the housing.

17. The optical image stabilization device of claim 16, wherein:
after the drive chip controls the reverse displacement of the stabilization module, the third elastic element and the fourth elastic element restore the stabilization module to a position without shaking through elastic deformation.
